(19) United States
(12) Patent Application Publication
(10) Pub. No.: US 2026/0044089 A1
(43) Pub. Date: Feb. 12, 2026

(54) LASER POSITIONING APPARATUS AND WAFER INSPECTION SYSTEM

(71) Applicant: DONGFANG JINGYUAN ELECTRON CO., LTD., Beijing (CN)

(72) Inventors: Chunying Han, Beijing (CN); Tao Mi, Beijing (CN); Yande Yang, Beijing (CN); Xiaohui Han, Beijing (CN)

(21) Appl. No.: 19/365,725

(22) Filed: Oct. 22, 2025

(30) Foreign Application Priority Data
Nov. 21, 2024 (CN) 202411677131.3

(51) Int. Cl. G03F 7/00; G01B 11/00; G01B 11/27

(52) U.S. Cl. CPC G03F 7/70775; G01B 11/002; G01B 11/27; G03F 7/70725

(57) ABSTRACT

The present application discloses a laser positioning apparatus and a wafer inspection system. The laser positioning apparatus comprises a stage, an orthogonality test feedback assembly, and an optical path assembly; the stage comprises a motion mechanism, a carrier, and a measurement mirror, the motion mechanism is configured to drive the carrier to move in a first direction and a second direction, the measurement mirror is disposed on the carrier, a first measurement surface of the measurement mirror intersects with the first direction, and a second measurement surface intersects with the second direction; an orthogonality test feedback assembly is provided with a first measurement head and a second measurement head, the first measurement head emitting a first laser beam toward the first measurement surface in the first direction, and the second measurement head emitting a second laser beam.

### CROSS-REFERENCE TO RELATED APPLICATIONS

This application claims priority to Chinese Patent Application No. 202411677131.3, titled “LASER POSITIONING APPARATUS AND WAFER INSPECTION SYSTEM” and filed on November 21, 2024, which is hereby incorporated by reference in its entirety.

### TECHNICAL FIELD

The present application belongs to the technical field of semiconductor, and in particular to a laser positioning apparatus and a wafer inspection system.

### BACKGROUND

With the development of semiconductor technology, higher requirements have been placed on semiconductor devices. When inspection or other operation is performed on a wafer, it is necessary to precisely position the stage bearing the wafer to improve measurement accuracy and defect inspection rate in advanced manufacturing processes.

In the related art, a wafer is carried by a stage, and the stage can drive the wafer to translate, thereby satisfying the displacement requirements for wafer inspection. The stage adopts a grating ruler for positioning; however, when the reference grating ruler is used to position the wafer, the distance between the grating ruler and the wafer is large, resulting in Abbe error in the measurement.

### SUMMARY

Embodiments of the present application provide a laser positioning apparatus and a wafer inspection system, which can improve positioning accuracy.

In a first aspect, an embodiment of the present application provides a laser positioning apparatus, which comprises: a stage, an orthogonality test feedback assembly and an optical path assembly; the stage comprises a motion mechanism, a carrier, and a measurement mirror, wherein the motion mechanism is configured to drive the carrier to move in a first direction and a second direction, the measurement mirror is disposed on the carrier, a first measurement surface of the measurement mirror intersects with the first direction, and a second measurement surface of the measurement mirror intersects with the second direction; the orthogonality test feedback assembly is provided with a first measurement head and a second measurement head, the first measurement head emitting a first laser beam toward the first measurement surface in the first direction, and the second measurement head emitting a second laser beam; the optical path assembly configured to split the second laser beam into a plurality of third laser beams emitting toward the second measurement surface in the second direction.

Optionally, the optical path assembly comprises a beam splitting assembly and a reflection assembly; the beam splitting assembly is located on an optical path of the second laser beam and is configured to split the second laser beam into a first reflection laser beam and one of the plurality of third laser beams; the reflection assembly is located on an optical path of the first reflection laser beam and is configured to reflect the first reflection laser beam into another one of the plurality of third laser beams.

Optionally, the beam splitting assembly comprises a first beam splitting mirror, the second laser beam and the first reflection laser beam are at a side of the first beam splitting mirror, and the third laser beam is at other side of the first beam splitting mirror; the reflection assembly comprises a reflecting mirror, and the first reflection laser beam and the third laser beam are at a side of the reflecting mirror.

Optionally, the beam splitting assembly further comprises a second beam splitting mirror, the second beam splitting mirror is located between the first beam splitting mirror and the reflecting mirror, and is configured to be transmitted through by the first reflection light beam to form one of the plurality of third laser beams.

Optionally, an included angle between the first reflection laser beam and the second laser beam is 90°; an included angle between the first reflection laser beam and the third laser beam is 90°.

Optionally, a transmittance-to-reflectance ratio of the first beam splitting mirror is 1:2, and a transmittance-to-reflectance ratio of the second beam splitting mirror is 1:1.

Optionally, the carrier comprises a mounting plate and a suction cup; the mounting plate is disposed on the motion mechanism, and the suction cup is disposed on the mounting plate; the measurement mirror is disposed on the mounting plate, a height of the measurement mirror is lower than a height of the suction cup, the first measurement surface of the measurement mirror is perpendicular to the first direction, the second measurement surface of the measurement mirror is perpendicular to the second direction, and the first measurement surface is perpendicular to the second measurement surface.

Optionally, the motion mechanism comprises a first motion mechanism and a second motion mechanism; the first motion mechanism is provided with a first grating ruler, the first motion mechanism is configured to move in the first direction, and the first grating ruler is configured to provide operation control of the first motion mechanism; the second motion mechanism is disposed on the first motion mechanism, and the second motion mechanism is provided with a second grating ruler, the second motion mechanism is configured to move in the second direction, and the second grating ruler is configured to provide operation control of the second motion mechanism.

In a second aspect, an embodiment of the present application provides a wafer inspection system, which comprises a device body and the laser positioning apparatus; the device body is provided with a plurality of inspection heads located above the stage and configured to inspect a wafer on the stage, and inspection points of a plurality of the inspection heads are located at intersection points of an optical path of the first laser beam and optical paths of the third laser beams respectively.

Optionally, the inspection head comprises a first inspection head, a second inspection head, and a third inspection head; the first inspection head is an electron optical inspection head, the second inspection head is a geometric optical inspection head, and the third inspection head is a deep ultraviolet geometric optical inspection head.

Embodiments of the present application provide a laser positioning apparatus and a wafer inspection system, wherein the laser positioning apparatus comprises a stage, an orthogonality test feedback assembly, and an optical path assembly. The stage can drive the wafer to move in the first direction and the second direction, and the measurement mirror is disposed on the stage, which can provide positioning reference for the orthogonality test feedback assembly. The first measurement head of the orthogonality test feedback assembly emits the first laser beam to the first measurement surface, the second laser beam emitted by the second measurement head is split into a plurality of third laser beams through the optical path assembly and emitted to the second measurement surface, so that the first laser beam and the plurality of third laser beams can be accurately positioned at the intersection points of the optical paths, the positioning accuracy is improved, and the Abbe error in measurement is reduced.

### BRIEF DESCRIPTION OF THE DRAWINGS

In order to illustrate technical solutions of embodiments of the present application more clearly, the drawings required for use in the embodiments of the present application will be briefly described below. For those skilled in the art, other drawings can also be obtained from these drawings without any inventive effort.

FIG. 1 is a schematic structural diagram of a laser positioning apparatus at a viewing angle according to some embodiments of the present application;

FIG. 2 is a schematic structural diagram of the laser positioning apparatus at another viewing angle according to some embodiments of the present application;

FIG. 3 is a schematic structural diagram of an optical path assembly according to some embodiments of the present application; and

FIG. 4 is a schematic structural diagram of another optical path assembly according to some embodiments of the present application.

### Reference numerals:

1, stage; 11, motion mechanism; 111-second motion mechanism; 1111, second grating ruler; 112, first motion mechanism; 1121, first grating ruler; 12, carrier; 13, measurement mirror; 131, first measurement surface; 132, second measurement surface; 2, orthogonality test feedback assembly; 21, first measurement head; 22, second measurement head; 23, orthogonality test feedback body; 3, optical path assembly; 31, beam splitting assembly; 311, first beam splitting mirror; 312, second beam splitting mirror; 32, reflection assembly; 321, reflecting mirror; 4, wafer; 5, first laser beam; 6, second laser beam; 7, third laser beam; 8, first reflection laser beam; 9, device body; 91, first inspection head; 92, second inspection head; 93, third inspection head; X, first direction; Y, second direction; L1, first center distance; L2, second center distance.

### DETAILED DESCRIPTION

Features of various aspects and exemplary embodiments of the present application will be described in detail below. In order to make objects, technical solutions and advantages of the present application clearer, the present application is further described in detail below with reference to the drawings and specific embodiments. It should be understood that the specific embodiments described herein are merely intended to explain the present application, rather than to limit the present application. For those skilled in the art, the present application can be implemented without some of these specific details. The following description of the embodiments is only to provide a better understanding of the present application by illustrating examples of the present application.

It should be noted that, in the present application, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include…” do not exclude the existence of additional identical elements in the process, method, article or device that includes the elements.

With the development of semiconductor technology and the advancements in process technology, the line widths of integrated circuits are becoming increasingly finer, placing higher and more demanding demands on circuit production processes. At the same time, semiconductor foundry companies are placing higher demands on semiconductor device to reduce costs, increase efficiency, improve production efficiency, and improve the utilization rate of cleanrooms.

When devices for optical inspection, exposure, or the like perform inspection or other operations on wafers, it is necessary to achieve global positioning and measurement of the stage bearing the wafers, thereby improving the measurement accuracy and defect inspection rate in advanced manufacturing processes. When inspecting wafers, the inspection device usually integrates multiple inspection modes, and inspects wafers on the same stage in multiple modes. Each inspection mode corresponds to an inspection head, and each inspection head itself has a certain volume. In terms of assembly design, in order to avoid mutual interference during the installation of multiple inspection heads, adjacent inspection heads are arranged at intervals; and since the carrier surface of the stage has a certain size (e.g., it may be a square carrier surface of 300 mm × 300 mm), the inspection points of multiple inspection heads can be distributed at different positions to form multiple inspection points.

In the related art, the stage includes an X-axis motion mechanism and a Y-axis motion mechanism, and positioning is achieved by controlling the displacement of the X-axis motion mechanism and the Y-axis motion mechanism with a grating ruler. However, when positioning multiple inspection points on a wafer, the distance between the grating ruler and the wafer is relatively far, resulting in an Abbe error in measurement. In view of this, embodiments of the present application provide a laser positioning apparatus and a wafer inspection system.

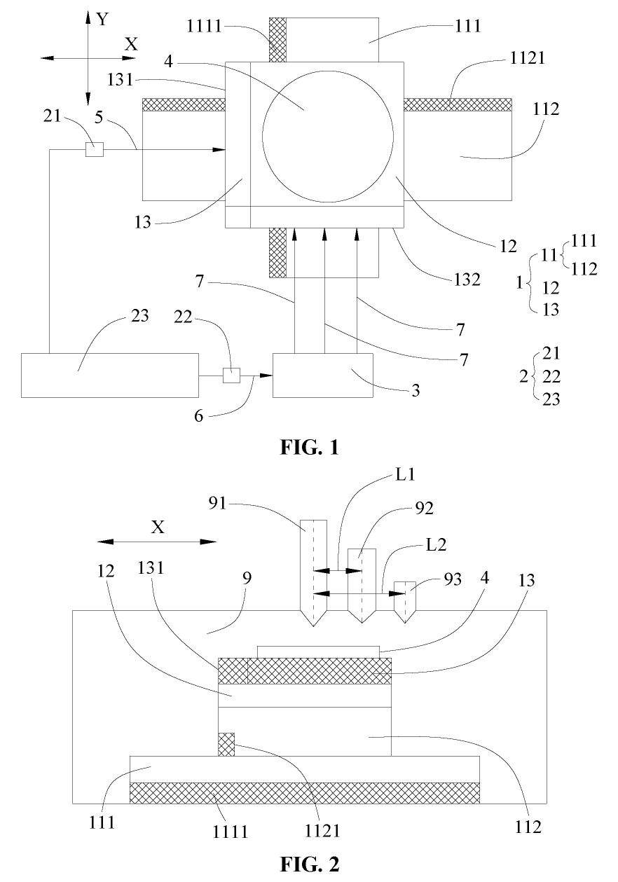

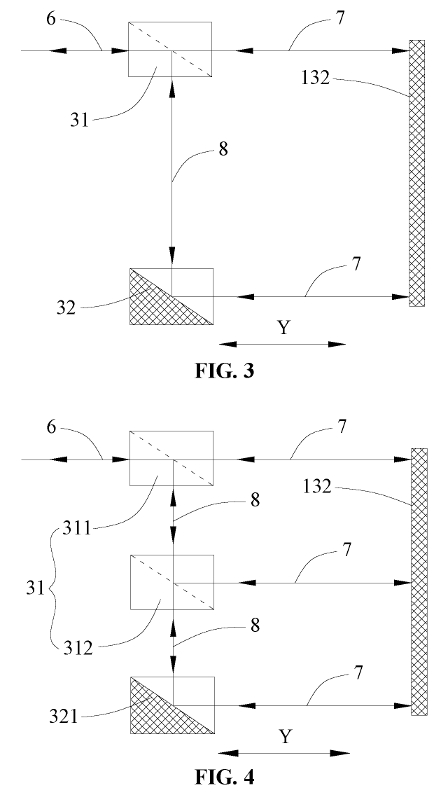

Referring to FIGS. 1 to 4, FIG. 1 is a schematic structural diagram of a laser positioning apparatus at a viewing angle according to some embodiments of the present application; FIG. 2 is a schematic structural diagram of a laser positioning apparatus at another viewing angle according to some embodiments of the present application; FIG. 3 is a schematic structural diagram of an optical path assembly according to some embodiments of the present application; and FIG. 4 is a schematic structural diagram of another optical path assembly according to some embodiments of the present application.

In a first aspect, as shown in FIGS. 1 and 2, embodiments of the present application provide a laser positioning apparatus including a stage 1, an orthogonality test feedback assembly 2, and an optical path assembly 3. The stage 1 includes a motion mechanism 11, a carrier 12, and a measurement mirror 13; the carrier 12 is disposed on the motion mechanism 11, and the motion mechanism 11 is configured to drive the carrier 12 to move in the first direction X and the second direction Y; the measurement mirror 13 is disposed on the carrier 12, the first measurement surface 131 of the measurement mirror 13 intersects with the first direction X, and the second measurement surface 132 of the measurement mirror 13 intersects with the second direction Y. The orthogonality test feedback assembly 2 is provided with a first measurement head 21 and a second measurement head 22, the first measurement head 21 emits a first laser beam 5 in a first direction X toward a first measurement surface 131, and the second measurement head 22 emits a second laser beam 6. The optical path assembly 3 receives the second laser beam 6 emitted by the second measurement head 22, splits the second laser beam 6 into multiple third laser beams 7, which are then emitted along the second direction Y toward the second measurement surface 132.

The stage 1 achieves movement in the first direction X and the second direction Y by using the motion mechanism 11, and the first direction X and the second direction Y intersect (e.g., the first direction X can be perpendicular to the second direction Y), so that the carrier 12 can be moved in a plane. The carrier 12 is disposed on the motion mechanism 11 and configured to provide a carrier for a workpiece such as a wafer 4, providing a bearing function. The measurement mirror 13 is disposed on the carrier 12, the first laser beam 5 is received by using the first measurement surface 131, the third laser beam 7 is received by using the second measurement surface 132, which can provide a positioning reference for the first laser beam 5 and the third laser beam 7.

The orthogonality test feedback assembly 2 may include an orthogonality test feedback body 23, a first measurement head 21, and a second measurement head 22. Each orthogonality test feedback body 23 is connected to a first measurement head 21 and a second measurement head 22, and the first measurement head 21 and the second measurement head 22 can cooperate with the orthogonality test feedback body 23 to achieve distance measurement. Exemplarily, the first laser beam 5 emitted by the first measurement head 21 reaches the first measurement surface 131 and returns; the second laser beam 6 emitted by the second measurement head 22 reaches the second measurement surface 132 and returns along the same path; the returned laser beam forms an interference pattern inside the orthogonality test feedback body 23, and when the position of the stage 1 changes, the optical path difference between the first laser beam 5 and the second laser beam 6 changes, resulting in a change in the interference pattern, and the orthogonality test feedback body 23 can calculate the displacement amount of the stage 1 through monitoring and analysis. The orthogonality test feedback assembly 2 may employ a laser interferometer.

Each orthogonality test feedback assembly 2 has only one first measurement head 21 and one second measurement head 22, and the first measurement head 21 and the second measurement head 22 can directly achieve plane positioning of one inspection point by emitting laser light, which cannot satisfy the requirements of positioning multiple inspection points. In this regard, the first measurement head 21 emits the first laser beam 5 along the first direction X toward the first measurement surface 131, so as to achieve accurate positioning of multiple inspection points in the first direction X. The second laser beam 6 emitted by the second measurement head 22 is emitted toward the optical path assembly 3, and the optical path assembly 3 can split the second laser beam 6 into multiple third laser beams 7 and emit multiple third laser beams 7 toward the second measurement surface 132 along the second direction Y, so that accurate positioning of multiple inspection points in the second direction Y can be achieved. One first laser beam 5 and multiple third laser beams 7 may form multiple intersection points in the optical path, thereby achieving global positioning of multiple inspection points. The first laser beam 5 and the third laser beams 7 each are located on a straight line in the inspection point positioning direction, so that the Abbe error can be reduced.

The optical path assembly 3 receives the second laser beam 6 and splits the second laser beam 6, which can split the second laser beam 6 into multiple third laser beams 7, and multiple third laser beams 7 and one first laser beam 5 can form multiple intersection points in the optical path, and the number of intersection points is consistent with the number of the third laser beams 7.

In the technical solution of above embodiments, the laser beam positioning apparatus includes a stage 1, an orthogonality test feedback assembly 2, and an optical path assembly 3. The stage 1 may serve as a support and a positioning reference. The orthogonality test feedback assembly 2 and the optical path assembly 3 can form a first laser beam 5 and multiple third laser beams 7, and the first laser beam 5 and multiple third laser beams 7 form multiple intersection points in the optical path, and each intersection point corresponds to an inspection point, so that the positioning of multiple inspection points can be achieved. The first laser beam 5 and the third laser beams 7 each are located on a straight line in the inspection point positioning direction, so that the Abbe error in measurement can be reduced, the positioning accuracy can be improved, and accurate positioning can be provided for multiple inspection points.

In some embodiments, as shown in FIG. 3, the optical path assembly 3 includes a beam splitting assembly 31 and a reflection assembly 32. The beam splitting assembly 31 is located in the optical path of the second laser beam 6 and configured to split the second laser beam 6 into a first reflection laser beam 8 and a third laser beam 7. The reflection assembly 32 is located in the optical path of the first reflection laser beam 8 and configured to reflect the first reflection laser beam 8 into another third laser beam 7.

The beam splitting assembly 31 is located in the optical path on which the second laser beam 6 is located, and the reflection assembly 32 is located in the optical path in which the first reflection laser beam formed by specular reflection of the second laser beam 6 on the beam splitting assembly 31 is located. The second laser beam 6 is incident on the beam splitting assembly 31, and the beam splitting assembly 31 can split the second laser beam 6 into two beams, one beam being the first reflection laser beam 8 and the other beam is the third laser beam 7. The first reflection laser beam 8 is incident on the reflection assembly 32, and the reflection assembly 32 can change the transmission direction of the first reflection laser beam 8, and after its the transmission direction changes, the first reflection laser beam 8 is converted into a third laser beam 7.

The beam splitting assembly 31 cooperates with the reflection assembly 32 to split one second laser beam 6 into two third laser beams 7. Exemplarily, the beam splitting assembly 31 can be a beam splitting mirror achieving a change in the number of laser beams and a change in the propagation path; and the reflection assembly 32 may be a reflecting mirror 321 achieving a change in the propagation path of the laser beams.

In the technical solution of above embodiments, the beam splitting assembly 31 and the reflection assembly 32 may split one second laser beam 6 into two third laser beams 7, and two third laser beams 7 are incident on the second measurement surface 132 along the second direction Y, and two third laser beams 7 and the first laser beam 5 may form two intersection points in the optical path, so that accurate positioning can be provided for two inspection points.

In some embodiments, as shown in FIG. 3, the beam splitting assembly 31 includes a first beam splitting mirror 311, a second laser beam 6 and a first reflection laser beam 8 are at one side of the first beam splitting mirror 311, and a third laser beam 7 is at the other side of the first beam splitting mirror 311. The reflection assembly 32 includes a reflecting mirror 321, and one side of the reflecting mirror 321 is the first reflection laser beam 8 and the third laser beam 7.

The second laser beam 6 is incident on the first beam splitting mirror 311, and the first beam splitting mirror 311 is configured to be transmitted through by the second laser beam 6 and reflect the second laser beam 6, a third laser beam 7 is formed after the first beam splitting mirror 311 is transmitted through by the second laser beam 6, and a first reflection laser beam 8 is formed after the first beam splitting mirror 311 reflects the second laser beam 6. The first reflection laser beam 8 is emitted to the reflecting mirror 321, the reflecting mirror 321 specularly reflects the first reflection laser beam, and another third laser beam 7 is formed after the propagation path is changed.

In the technical solution of above embodiments, the second laser beam 6 and the first reflection laser beam 8 are located on the same side of the first beam splitting mirror 311, and specular reflection is conducive to obtaining the optical path, thereby facilitating arranging the position and angle of the reflecting mirror 321.

In some embodiments, as shown in FIG. 4, the beam splitting assembly 31 further includes a second beam splitting mirror 312, the second beam splitting mirror 312 is located between the first beam splitting mirror 311 and the reflecting mirror 321, and is configured to be transmit through by the first reflection laser beam to form a third laser beam 7.

The second beam splitting mirror 312 is located in the optical path of the first reflection laser beam 8, the first reflection laser beam 8 is emitted to the second beam splitting mirror 312, the second beam splitting mirror 312 is transmitted through by a part of the first reflection laser beam to the reflecting mirror 321, and reflects the other part of the first reflection laser beam, which is converted into the third laser beam 7 after the propagation path changes.

The third laser beam 7 formed at the first beam splitting mirror 311 is formed by the first beam splitting mirror 311 being transmitted through; the third laser beam 7 formed at the second beam splitting mirror 312 is formed by reflecting from the second beam splitting mirror 312; the third laser beam 7 formed at the reflecting mirror 321 is formed by reflecting from the reflecting mirror 321.

In the technical solution of above embodiments, the optical path assembly 3 includes a first beam splitting mirror 311, a second beam splitting mirror 312, and a reflecting mirror 321, and after the second laser beam 6 is emitted to the optical path assembly 3, three third laser beams 7 can be formed, and three third laser beams 7 and one first laser beam 5 can form three intersection points in the optical path, so that three inspection points can be accurately positioned.

In some embodiments, as shown in FIG. 4, the included angle between the first reflection laser beam 8 and the second laser beam 6 is 90°; the included angle between the first reflection laser beam 8 and the third laser beam 7 is 90°.

The first reflection laser beam 8 is arranged perpendicular to the second laser beam 6, and the first beam splitting mirror 311 is a 90° beam splitting mirror, which can split the incident light at an angle of 90° (splitting the second laser beam 6 into a third laser beam 7 and a first reflection laser beam 8 at an angle of 90 °). The first reflection laser beam 8 is arranged perpendicular to the third laser beam 7, and the second beam splitting mirror 312 is a 90° beam splitting mirror, which can split the incident light at an angle of 90° (a third laser beam 7 is split from the first reflection laser beam 8).

In the technical solution of above embodiments, the first reflection laser beam 8 is perpendicular to the second laser beam 6 and the third laser beam 7 each, and the second laser beam 6 is perpendicular to the third laser beam 7, which is conducive to controlling the optical path of the laser beam, and the arrangement of the first beam splitting mirror 311, the second beam splitting mirror 312, and the third beam splitting mirror is more convenient.

In some embodiments, as shown in FIG. 4, the transmittance-to-reflectance ratio of the first beam splitting mirror 311 is 1:2, and the transmittance-to-reflectance ratio of the second beam splitting mirror 312 is 1:1.

When facing an incident beam, the first beam splitting mirror 311 is transmitted by one-third of the intensity of the incident beam and reflects two-thirds of the intensity of the incident beam, and the second beam splitting mirror 312 is transmitted by one-half of the intensity of the incident beam and reflects one-half of the intensity of the incident beam. When being emitted to the first beam splitting mirror 311, the second laser beam 6 is transmitted through the first beam splitting mirror 311 to form the 1st third laser beam 7 and is reflected to form a first reflection laser beam 8, the 1st third laser beam 7 having one-third of the intensity of the second laser beam 6, and the first reflection laser beam 8 having two-thirds of the intensity of the second laser beam 6. The first reflection laser beam 8 is emitted to the second beam splitting mirror 312, and is reflected at the second beam splitting mirror 312 to form a 2nd third laser beam 7, the intensity of the 2nd third laser beam 7 is one-half of the intensity of the first reflection laser beam 8, and the first reflection laser beam 8 having the remaining one-half of the intensity passes through the second beam splitting mirror 312 and is specularly reflected by the reflecting mirror 321 to form the 3rd third laser beam 7.

In the technical solution of above embodiments, the transmittance-to-reflectance ratio of the first beam splitting mirror 311 is 1:2, the transmittance-to-reflectance ratio of the second beam splitting mirror 312 is 1:1, and three third laser beams 7 formed by the second laser beam 6 passing through the first beam splitting mirror 311, the second beam splitting mirror 312, and the reflecting mirror 321 have equal intensity, so that the positioning accuracy can be improved.

In some embodiments, as shown in FIGS. 1 and 2, the carrier 12 includes a mounting plate and a suction cup. The mounting plate is disposed on the motion mechanism 11, and the suction cup is disposed on the mounting plate. The measurement mirror 13 is also disposed on the mounting plate, and the height of the measurement mirror 13 is lower than the height of the suction cup. The first measurement surface 131 of the measurement mirror 13 is perpendicular to the first direction X, the second measurement surface 132 of the measurement mirror 13 is perpendicular to the second direction Y, and the first measurement surface 131 is perpendicular to the second measurement surface 132.

The mounting plate is disposed on the motion mechanism 11 and can provide mounting positions for the suction cup and the measurement mirror 13, and the suction cup is disposed on the mounting plate to absorb the wafer 4 and fix the wafer 4 to the suction cup. The measurement mirror 13 is disposed on the mounting plate and may be provided with a gap from the suction cup, or may attach to the suction cup. When the suction cup is disposed on the mounting plate, the distance between the bearing surface of the suction cup and the mounting plate is H1; when the measurement mirror 13 is disposed on the mounting plate, the distance between the top surface of the measurement mirror and the mounting plate is H2, and H1 > H2.

The measurement mirror 13 may have an integrated structure or a split structure. Exemplarily, when the measurement mirror 13 is an integrated structure, the measurement mirror 13 can be divided into two parts perpendicular to each other, the first measurement surface 131 is located on the first part, the second measurement surface 132 is located on the second part, one end of the first part is connected to one end of the second part, and the first part is perpendicular to the second part. When the measurement mirror 13 is a split structure, the measurement mirror 13 may include a first measurement mirror and a second measurement mirror, the first measurement surface 131 is disposed on the first measurement mirror, the second measurement surface 132 is disposed on the second measurement mirror, and the first measurement mirror is perpendicular to the second measurement mirror.

In the technical solution of above embodiments, the first measurement surface 131 of the measurement mirror 13 is perpendicular to the first direction X, and the first measurement surface 131 is disposed perpendicular to the first laser beam 5; the second measurement surface 132 of the measurement mirror 13 is perpendicular to the second direction Y, and the second measurement surface 132 is disposed perpendicular to the third laser beam 7, so that the positioning accuracy can be improved. The height of the measurement mirror 13 is lower than the height of the suction cup, which can avoid contact with the wafer 4, thereby avoiding collide with the wafer 4.

In some embodiments, as shown in FIGS. 1 and 2, the motion mechanism 11 includes a first motion mechanism 112 and a second motion mechanism 111. The first motion mechanism 112 is provided with a first grating ruler 1121, and is configured to move in the first direction X, and the first grating ruler 1121 is configured to provide operation control of the first motion mechanism 112. The second motion mechanism 111 is disposed on the first motion mechanism 112, and the second motion mechanism 111 is provided with a second grating ruler 1111, is configured to move in the second direction Y, and the second grating ruler 1111 is configured to provide operation control of the second motion mechanism 111.

The first motion mechanism 112 is translated in the first direction X, the second motion mechanism 111 is translated in the second direction Y, and the first direction X is perpendicular to the second direction Y, so that the translation of the motion mechanism 11 in a plane can be achieved. The first grating ruler 1121 can be externally connected to a host computer to control the moving distance of the first motion mechanism 112; the second grating ruler 1111 can be externally connected to a host computer to control the moving distance of the second motion mechanism 111.

The first laser beam 5 is perpendicular to the first measurement surface 131, the third laser beam 7 is perpendicular to the second measurement surface 132, and the first measurement surface 131 is perpendicular to the second measurement surface 132, which can establish rectangular coordinates for positioning during positioning.

In the technical solution of above embodiments, by providing the first motion mechanism 112 and the second motion mechanism 111, the motion mechanism 11 can achieve control of translation in the first direction X and the second direction Y individually, and the displacement of the suction cup can be controlled by the first grating ruler 1121 and the second grating ruler 1111, thereby improving the displacement accuracy of the suction cup.

In the second aspect, as shown in FIG. 2, embodiments of the present application provide a wafer inspection system including a device body 9 and a laser positioning apparatus provided in the above embodiments. The device body 9 is provided with multiple inspection heads, multiple inspection heads are located above the stage 1 for inspecting the wafer 4 on the stage 1, and the inspection points of multiple inspection heads are respectively located at the intersection points of the optical path of the first laser beam 5 and the optical paths of the third laser beams 7.

The device body 9 is a component of the wafer inspection system that mainly operates the inspection function, and further provides a mounting basis for the laser positioning apparatus. The inspection heads serve as ports through which the device body 9 inspects the wafer 4, and during inspection, the inspection points coincides with the intersection points of the optical path of the first laser beam 5 and the optical paths of the third laser beams 7.

In the above embodiments, by disposing the intersection points of the optical path of the first laser beam 5 and the optical paths of the third laser beams 7, the laser positioning apparatus can provide accurate positioning for multiple inspection points, thereby reducing the Abbe error during inspection of the wafer 4.

In some embodiments, as shown in FIG. 2, the inspection heads include a first inspection head 91, a second inspection head 92, and a third inspection head 93; the first inspection head 91 is an electron optical inspection head, the second inspection head 92 is a geometric optical inspection head, and the third inspection head 93 is a deep ultraviolet geometric optical inspection head.

On the device body 9, multiple inspection heads are not located at one place in the space, but there is a center distance deviation between adjacent inspection heads, and multiple inspection points of multiple inspection heads are located on a straight line, and the straight line coincides with the optical path of the first laser beam 5. The first laser beam 5 may provide positioning in the first direction X for multiple inspection points. Each third laser beam 7 corresponds to an inspection point, thereby providing positioning in the second direction Y for multiple inspection points.

The electron optical inspection head, in collaboration with the device body 9, can measure the feature size and inspect the size of the photoresist pattern on the wafer 4 and can perform defect inspection to detect minute defects on the surface of the wafer 4; it can also be equipped with an energy scattering spectrometer for composition analysis to analyze the elemental composition of the surface of wafer 4.

The geometric optical inspection head cooperates with the device body 9 to perform appearance and structure inspection, observe the appearance and morphology of the wafer 4, and inspect defects such as scratches, cracks, and contamination on the surface of the wafer 4; the failure part can be analyzed, the surface morphology of the failure part can be observed, and the failure cause can be determined; metallographic analysis may be performed to analyze parameters such as grain size, shape, and distribution of the wafer 4.

The deep ultraviolet geometric optical inspection head cooperates with the device body 9, and can use deep ultraviolet rays as a light source to focus, transmit and control light, and inspect the size, surface finish, flatness, thickness, shape of the wafer 4.

In the technical solutions of above embodiments, the device body 9 is equipped with an electron optical inspection head, a geometric optical inspection head, and a deep ultraviolet geometric optical inspection head, and the wafer 4 can be inspected in various forms, and the inspection points formed by the electron optical inspection head, the geometric optical inspection head, and the deep ultraviolet geometric optical inspection head when inspecting the wafer 4 are positioned by the first laser beam 5 and multiple third laser beams 7 in one-to-one correspondence, so that the positioning accuracy during inspection can be improved.

In some embodiments, as shown in FIGS. 1, 2 and 4, the wafer inspection system includes a device body 9 and a laser positioning apparatus, and the device body 9 is provided with a first inspection head 91, a second inspection head 92, and a third inspection head 93. The first inspection head 91 is an electron optical inspection head, the second inspection head 92 is a geometric optical inspection head, and the third inspection head 93 is a deep ultraviolet geometric optical inspection head. The detection modes of the wafer inspection system include SEM (electron optics) mode, OM (geometric optics) mode, and DUV (deep ultraviolet geometric optics) mode. The center distance deviation between the first inspection head 91 and the second inspection head 92 is a first center distance L1, and the center distance deviation between the first inspection head 91 and the third inspection head 93 is a second center distance L2. The laser positioning apparatus is disposed on the device body 9 and includes a stage 1, an orthogonality test feedback assembly 2, and an optical path assembly 3. The stage 1 includes a motion mechanism 11, a carrier 12, and a measurement mirror 13. The motion mechanism 11 includes a first motion mechanism 112 (provided with a first grating ruler 1121) translating in a first direction X, a second motion mechanism 111 (provided with a second grating ruler 1111) translating in a second direction Y, the second motion mechanism 111 is disposed on the first motion mechanism 112, and the second direction Y is perpendicular to the first direction X. The mounting plate of the carrier 12 is disposed on the second motion mechanism 111, the suction cup is disposed on the mounting plate, the measurement mirror 13 is disposed on the mounting plate, and the top surface of the measurement mirror 13 is lower than the bearing surface of the suction cup. The first measurement surface 131 of the measurement mirror 13 is disposed perpendicular to the second measurement surface 132, the first measurement surface 131 is perpendicular to the first direction X, and the second measurement surface 132 is perpendicular to the second direction Y. In the second direction Y, the length of the first measurement surface 131 is 300 mm; in the first direction X, the length of the second measurement surface 132 is 300 mm, which can provide a positioning reference for the wafer 4 having a diameter of 300 mm. The optical path assembly 3 includes a first beam splitting mirror 311, a second beam splitting mirror 312, and a reflecting mirror 321.

The first laser beam 5 emitted by the first measurement head 21 is emitted perpendicular to the first measurement surface 131 along the first direction X and can provide positioning in the first direction X for the inspection points of the first inspection head 91, the second inspection head 92, and the third inspection head 93 on the wafer 4. The second laser beam 6 emitted by the second measurement head 22 is emitted toward the first beam splitting mirror 311 and is transmitted through the first beam splitting mirror 311 to form the 1st third laser beam 7, and the 1st third laser beam 7 is emitted perpendicularly toward the second measurement surface 132 along the second direction Y, which can provide positioning in the second direction Y for the inspection points of the first inspection head 91 on the wafer 4. The 2nd third laser beam 7 is formed on the second beam splitting mirror 312 by reflecting, and the 2nd third laser beam 7 is perpendicularly emitted toward the second measurement surface 132 in the second direction Y, which can provide positioning in the second direction Y for the inspection points of the second inspection head 92 on the wafer 4. The 3rd third laser beam 7 is formed on the reflecting mirror 321 by reflecting, and the 3rd third laser beam 7 is perpendicularly emitted toward the second measurement surface 132 in the second direction Y, which can provide positioning in the second direction Y for the inspection points of the third inspection head 93 on the wafer 4.

When the first inspection head 91, the second inspection head 92, and the third inspection head 93 are positioned, the first laser beam 5 is located on a straight line in which the first inspection head 91, the second inspection head 92, and the third inspection head 93 are positioned in the first direction X, the first laser beam is located on a straight line in which the first inspection head 91 is positioned in the second direction Y, the second laser beam is located on a straight line in which the second detection head 92 is positioned in the second direction Y, and the third laser beam is located on a straight line in which the third inspection head 93 is positioned in the second direction Y. During positioning, the Abbe error can be reduced and the positioning accuracy can be improved. A set of orthogonality test feedback assembly 2 and a set of optical path assembly 3 are adopted to cooperate with each other for positioning, which allows simple operation, low material cost, and high, stable, and reliable positioning accuracy.

The above are only specific implementations of the present application, those skilled in the art may clearly understand that the specific operating processes of the above systems, modules and units may be referred to the corresponding processes in the embodiments of the foregoing method, which is not repeated here for the convenience and brevity of the description. It should be understood that the protection scope of the present application is not limited to this, and those skilled in the art can easily think of various equivalent modifications or replacements within the technical scope disclosed in the present application, and these modifications or replacements should all be covered within the scope of protection of the present application.

What is claimed is:

1. A laser positioning apparatus comprising:
a stage comprising a motion mechanism, a carrier, and a measurement mirror, wherein the motion mechanism is configured to drive the carrier to move in a first direction and a second direction, the measurement mirror is disposed on the carrier, a first measurement surface of the measurement mirror intersects with the first direction, and a second measurement surface of the measurement mirror intersects with the second direction;
an orthogonality test feedback assembly provided with a first measurement head and a second measurement head, wherein the first measurement head is configured to emit a first laser beam toward the first measurement surface in the first direction, and the second measurement head is configured to emit a second laser beam;
an optical path assembly configured to split the second laser beam into a plurality of third laser beams emitting toward the second measurement surface in the second direction.

2. The laser positioning apparatus according to claim 1, wherein the optical path assembly comprises:
a beam splitting assembly located in an optical path of the second laser beam and configured to split the second laser beam into a first reflection laser beam and one of the plurality of third laser beams; and
a reflection assembly located in an optical path of the first reflection laser beam and configured to reflect the first reflection laser beam into another one of the plurality of third laser beams.

3. The laser positioning apparatus according to claim 2, wherein the beam splitting assembly comprises a first beam splitting mirror, the second laser beam and the first reflection laser beam are at a side of the first beam splitting mirror, and the one of the plurality of third laser beams is at another side of the first beam splitting mirror; and
the reflection assembly comprises a reflecting mirror, and the first reflection laser beam and the another one of the plurality of third laser beams are at a side of the reflecting mirror.

4. The laser positioning apparatus according to claim 3, wherein the beam splitting assembly further comprises a second beam splitting mirror that is located between the first beam splitting mirror and the reflecting mirror and that is configured to be transmitted through by the first reflection light beam to form one of the plurality of third laser beams.

5. The laser positioning apparatus according to claim 3, wherein an included angle between the first reflection laser beam and the second laser beam is 90°; and
an included angle between the first reflection laser beam and the one of the plurality of the third laser beams is 90°.

6. The laser positioning apparatus according to claim 4, wherein a transmittance-to-reflectance ratio of the first beam splitting mirror is 1:2, and a transmittance-to-reflectance ratio of the second beam splitting mirror is 1:1.

7. The laser positioning apparatus according to claim 1, wherein the carrier comprises a mounting plate and a suction cup;
the mounting plate is disposed on the motion mechanism, and the suction cup is disposed on the mounting plate; and
the measurement mirror is disposed on the mounting plate, a height of the measurement mirror is lower than a height of the suction cup, the first measurement surface of the measurement mirror is perpendicular to the first direction, the second measurement surface of the measurement mirror is perpendicular to the second direction, and the first measurement surface is perpendicular to the second measurement surface.

8. The laser positioning apparatus according to claim 1, wherein the motion mechanism comprises:
a first motion mechanism provided with a first grating ruler and configured to move in the first direction, the first grating ruler being configured to provide operation control of the first motion mechanism; and
a second motion mechanism disposed on the first motion mechanism and provided with a second grating ruler, the second motion mechanism being configured to move in the second direction, and the second grating ruler being configured to provide operation control of the second motion mechanism.

9. A wafer inspection system comprising:
a device body; and
a laser positioning apparatus comprising: a stage comprising a motion mechanism, a carrier, and a measurement mirror, wherein the motion mechanism is configured to drive the carrier to move in a first direction and a second direction, the measurement mirror is disposed on the carrier, a first measurement surface of the measurement mirror intersects with the first direction, and a second measurement surface of the measurement mirror intersects with the second direction; an orthogonality test feedback assembly provided with a first measurement head and a second measurement head, wherein the first measurement head is configured to emit a first laser beam toward the first measurement surface in the first direction, and the second measurement head is configured to emit a second laser beam; an optical path assembly configured to split the second laser beam into a plurality of third laser beams emitting toward the second measurement surface in the second direction,
wherein the device body is provided with a plurality of inspection heads located above the stage and configured to inspect a wafer on the stage, and inspection points of the plurality of inspection heads are located at intersection points of an optical path of the first laser beam and optical paths of the third laser beams respectively.

10. The wafer inspection system according to claim 9, wherein the plurality of inspection heads comprises:
a first inspection head that is an electron optical inspection head;
a second inspection head that is a geometric optical inspection head; and
a third inspection head that is a deep ultraviolet geometric optical inspection head.
